(19) United States
(12) Patent Application Publication
(10) Pub. No.: US 2007/0212874 A1
(43) Pub. Date: Sep. 13, 2007

(54) Method for filling shallow isolation trenches and other recesses during the formation of a semiconductor device and electronic systems including the semiconductor device

(75) Inventor: Sukesh Sandhu, Boise, ID (US)

Correspondence Address: MICRON TECHNOLOGY, INC., 8000 FEDERAL WAY, MAIL STOP 525, BOISE, ID, 83707-0006, US

(73) Assignee: Micron Technology, Inc.

(21) Appl. No.: 11/371,680

(22) Filed: Mar. 8, 2006

(51) Int. Cl. H01L 21/4763

(52) U.S. Cl. 438/637

(57) ABSTRACT

A method for filling a shallow isolation trench comprises partially filling the trench with a first material, then filling the trench the rest of the way with a second material. For the first material, a substance which flows more easily into narrow, deep trenches is selected, while for the second material, a substance which provides good electrical isolation is selected. In one embodiment, the first material may comprise silicon nitride or polysilicon and the second material may comprise high density plasma oxide (HDP). A trench filled using an embodiment of the inventive method is also described.

### FIELD OF THE INVENTION

This invention relates to the field of semiconductor manufacture and, more particularly, to a method for filling a trench, such as a shallow trench used as field isolation, during the formation of a semiconductor device.

### BACKGROUND OF THE INVENTION

During the manufacture of semiconductor devices such as flash electrically-erasable programmable read-only memories (EPROMs), random-access memories (RAMs), logic devices, microprocessors, etc., several features are commonly formed over and within a semiconductor wafer. For example, conductively implanted regions within the semiconductor wafer are commonly electrically isolated from each other using shallow trench isolation (STI, field oxide). In one conventional process, a semiconductor wafer is implanted with conductive dopants to a first depth, then a trench is formed within the semiconductor wafer. The trench is typically formed to a depth below the depth of the implanted region. Next, the trench is filled with a dielectric layer such as silicon dioxide or silicon nitride. The dielectric layer is then removed from over horizontal portions of the semiconductor wafer such that the dielectric remains only in the trench. Wafer processing then continues to form features such as transistors and storage capacitors.

A continuing goal of semiconductor design and process engineers is to decrease the size of features formed over and within the semiconductor wafer. This includes forming narrower STI trenches. However, with narrower trenches it becomes more difficult to sufficiently fill the trenches with the isolation layer, as voids may form within the isolation material. While a gap filled with air or another gas may provide suitable electrical isolation for some uses (for example U.S. Pat. No. 6,627,529 by Philip J. Ireland, assigned to Micron Technology, Inc. and incorporated herein by reference as if set forth in its entirety), a gap within STI may have undesirable effects on the electrical operation of a completed semiconductor device such as a flash memory device. Negative effects may result from poor isolation due to the exposure of these voids during subsequent processing acts, which may provide a path through which an etch gas may reach to the underlying silicon to provide an electron leakage path and result in device failure. Also, a void in the isolation may be exposed during removal of the layer from over horizontal portions of the semiconductor wafer to result in a conductive stringer formed within the void during subsequent processing. A stringer may lead to electrical shorting between two or more conductive features, thereby resulting in an unreliable or nonfunctional device.

A process for forming dielectric such as shallow trench isolation which results in a more complete fill within the STI trenches, and a semiconductor device resulting from the process, would be desirable.

### SUMMARY OF THE INVENTION

The present invention provides a method which, among other advantages, reduces problems associated with the manufacture of semiconductor devices, particularly problems resulting during formation of shallow trench isolation (STI). During the conventional formation of dielectric material within the STI trench, gaps may form in the dielectric to provide an incomplete fill of the trench. In accordance with one embodiment of the invention, a first material is formed to partially fill the STI trench, then a second material is formed to fill the remainder of the trench. The first material is selected for its flowability, although it may be less desirable as an isolation material, while the second material is selected for its isolation properties, although its flowability may be less desirable than the first material. As an STI trench is typically narrower at the bottom than at the top, the more flowable material may more easily fill the narrower portions of the trench without voiding.

Advantages will become apparent to those skilled in the art from the following detailed description read in conjunction with the appended claims and the drawings attached hereto.

### BRIEF DESCRIPTION OF THE DRAWINGS

FIGS. 1-12 are cross sections depicting in-process structures formed using an embodiment of the invention to form shallow trench isolation;

FIG. 13 is an isometric depiction of various components which may be manufactured using devices formed with an embodiment of the present invention; and

FIG. 14 is a block diagram of an exemplary use of the invention to form part of a memory device having a storage transistor array.

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE ILLUSTRATED EMBODIMENTS

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but may be based on silicon-germanium, silicon-on-insulator, silicon-on-sapphire, germanium, or gallium arsenide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein. The term “about” indicates that the value listed may be somewhat altered, as long as the alteration does not result in an excessive negative impact to the process or structure. A “spacer” indicates a layer, typically dielectric, formed as a conformal blanket layer over uneven topography then anisotropically etched to remove horizontal portions of the layer and leaving vertical portions of the layer.

An exemplary embodiment of an inventive method for forming a semiconductor device comprising shallow trench isolation (STI) is depicted in FIGS. 1-12. FIG. 1 depicts a portion of a semiconductor wafer 10, a sacrificial pad oxide 12 (silicon dioxide) formed on the wafer 10, and a sacrificial layer 14 such as silicon nitride formed on the pad oxide. The pad oxide 12 protects the semiconductor wafer 10 from damage during formation of layer 14, particularly when layer 14 is a silicon nitride layer, and may not be necessary depending on what material is used for layer 14. FIG. 1 further depicts a patterned photoresist layer 16 formed over layer 14. Resist 16 comprises spaces 18, and will be used to define shallow isolation trenches. The structure of FIG. 1, which may comprise other features not depicted and not immediately germane to the present invention, may be formed by one of ordinary skill in the art.

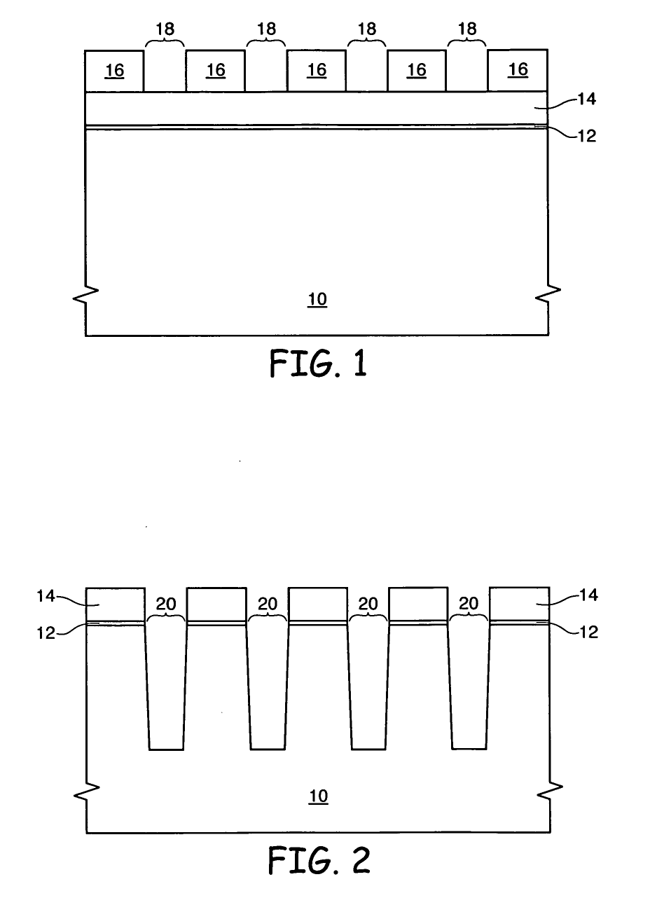

After forming the FIG. 1 structure, an anisotropic etch is performed to etch layers 14, 12, and 10. Subsequently, resist layer 16 is removed to result in the structure of FIG. 2. FIG. 2 depicts shallow isolation trenches 20 formed within the semiconductor wafer 10. In a typical embodiment with current processing techniques and for illustration purposes only, the trench portion within the wafer (i.e. not including the pad oxide 12 and the sacrificial silicon nitride layer 14) may be about 2,500 Å (±500 Å) deep, about 450 Å (±100 Å) wide at the bottom, and about 600 Å (±100 Å) wide at the top. Thus the trench with this embodiment has an aspect ratio of between about 5:1 to about 8:1, although the process described herein may have even greater utility with increasing aspect ratios.

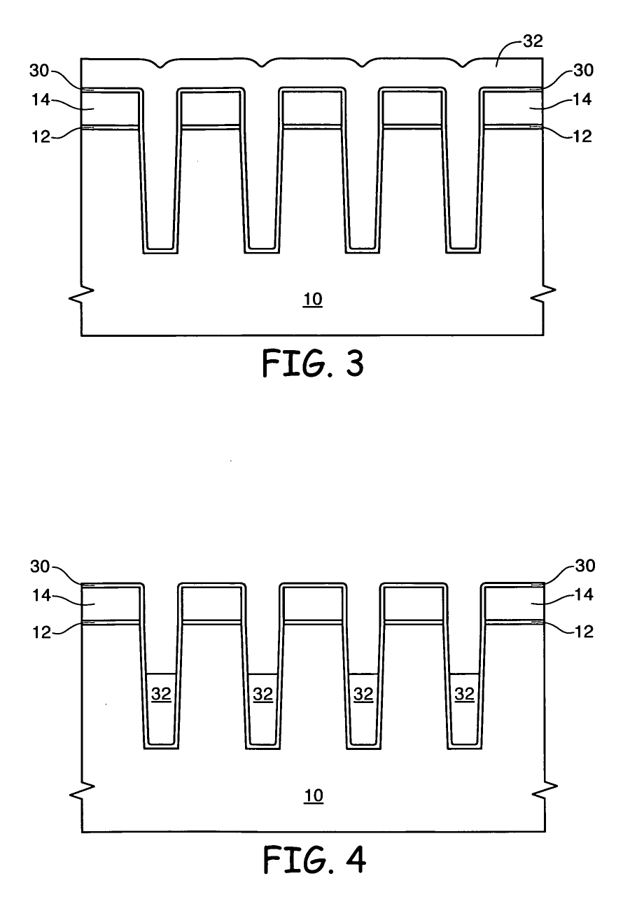

After forming the FIG. 2 structure, a thin conformal liner 30 is formed, then the trenches 20 are filled with a first fill material 32 as depicted in FIG. 3. The liner 30 may comprise in situ steam-generated (ISSG) oxide, thermal oxide, or high-temperature deposited oxide (HTO), and may be formed to between about 35 Å and about 65 Å thick. The first fill material 32 may comprise silicon nitride or amorphous silicon (a-Si), although polysilicon or another material may also function. Whichever material is selected for the first fill layer, the layer is formed in accordance with known techniques. In this embodiment, the first fill material 32 completely fills the trench 30 formed in the semiconductor wafer 10 and fills the openings in the pad oxide 12 and the silicon nitride layer 16. However, in other embodiments the first fill material may flow into the trenches to fill the trench portion in the semiconductor wafer only about half way, or generally to any level, for example between about one quarter to about three quarters full. While the material selected for the first fill layer may not provide an ideal isolation layer, it will fill the trench portion in the wafer due to its good flowability, particularly the narrower bottom half of the trench, without voiding or with minimal voiding while still providing adequate isolation.

After forming the FIG. 3 structure, any excess first fill layer material 32 is removed, for example using a planarization process such as chemical mechanical polishing (CMP) to planarize the layer, then by using a wet or dry etch to recess the layer within the trench as depicted in FIG. 4. If silicon nitride is used as layer 32, it may be etched selective to the oxide liner 30 (i.e. it etches silicon nitride at a much faster rate than it etches oxide) using hot phosphoric acid (hot phos). If polysilicon or a-Si is used as layer 32, it may be recessed selective to the oxide layer 30 using tetramethyl ammonium hydroxide (TMAH) or with a dry etch. During this recess, the oxide liner 30 protects silicon nitride structures 14, and possibly other structures normally exposed at nondepicted wafer locations.

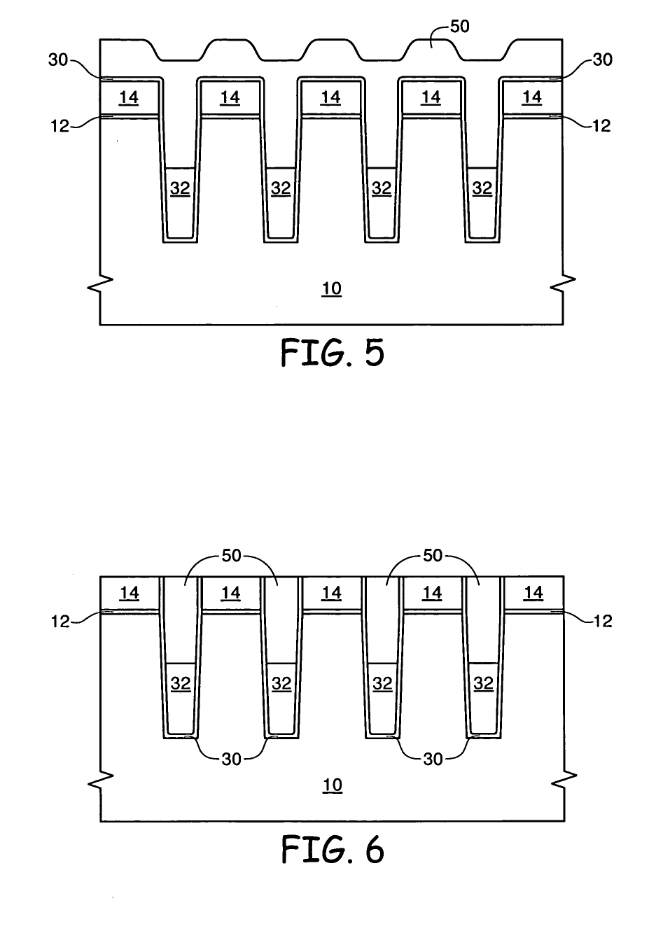

After forming the FIG. 4 structure, a second fill layer 50 is formed to contact the first fill layer 32 as depicted in FIG. 5. The second fill layer 50 is selected more for its isolation properties than for its flowability. The trench is typically tapered and, as such, flowability is less of a concern with the partially filled trench as the remaining unfilled upper portion of the trench is wider than the lower portion. Further, because of the partial fill, the remaining trench portion has a lower aspect ratio and it is easier to complete the fill with the less flowable material than it would be to fill the entire trench. Suitable materials for the second fill material 40 include high density plasma (HDP) chemical vapor deposited (CVD) silicon dioxide and spun-on glass (SOG). The second fill layer 50 is formed to a sufficient thickness to cover silicon nitride 16 with between about 600 Å to about 1,000 Å of material, so that the remaining portions of the trench in wafer 10, and the openings in pad oxide 12 and silicon nitride layer 16 are completely filled.

Next, the second fill layer 50 is planarized, for example using CMP alone or in conduction with a subsequent wet or dry etch to result in the FIG. 6 structure. The planarization is targeted to terminate just as the liner 30 is removed from over layer 14 so that removal of any portion of layer 50 below the upper surface of layer 14 is minimized.

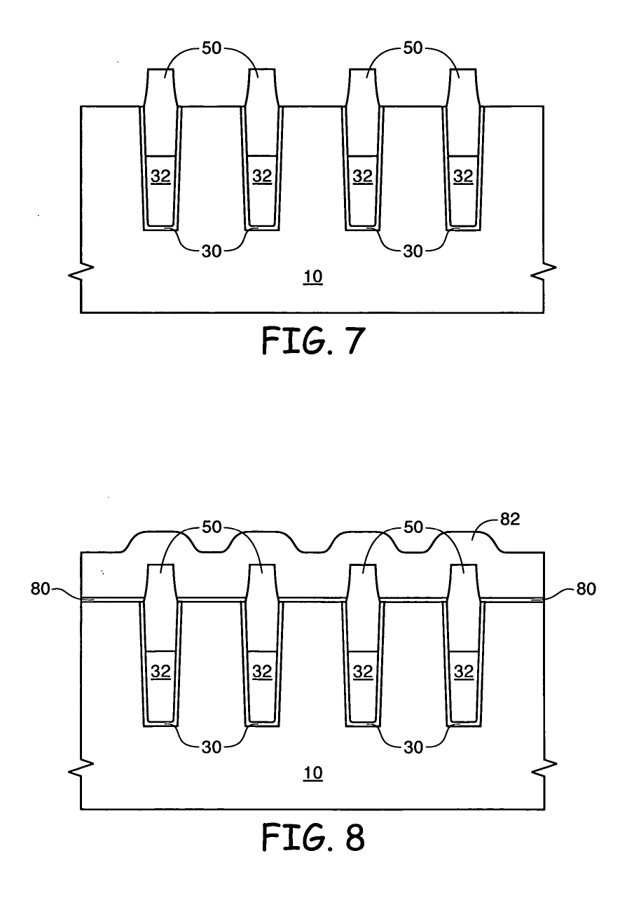

After performing CMP on the second fill layer 50 of FIG. 5 to result in the FIG. 6 structure, an etch is performed to remove layer 14. In this embodiment, the etch used should remove silicon nitride selective to oxide liner 30 and pad oxide 12, for example using hot phos. Subsequent to removing layer 14, the pad oxide is removed selective to the semiconductor wafer, for example using hydrofluoric acid or another wet or a dry etch. In addition to removing layer 12, this etch may also remove a portion of layers 50 and liner 30 to result in the structure of FIG. 7, wherein the second fill layer protrudes from the semiconductor wafer.

The process may continue to form damascene structures, for example transistor floating gates for a flash memory device. With this process flow, a tunnel oxide layer 80 is formed over the wafer surface as depicted in FIG. 8, then a blanket polysilicon floating gate layer 82 is formed over the wafer surface. To maximize the thickness of the floating gate, the upper surface of the blanket floating gate layer 82 should be at a level above the upper surface of the second fill layer 50.

It is evident that the eventual thickness of the floating gate layer is determined by layer 50, with the thickness of layer 50 being determined by the thickness of layer 14. Thus the dimensions of layer 14 are targeted for maximum benefit to the structure being formed. Further, if a fairly conductive material is used for the first fill layer 32, it is preferable to maintain a minimum distance between the upper surface of the first fill layer 32 and the tunnel oxide 80 of FIG. 8 to ensure proper electrical operation of the completed transistor. It is preferable to maintain a distance of at least about 500 Å (±100 Å) between the upper surface of the first fill layer 32 and the lower surface of the tunnel oxide 80.

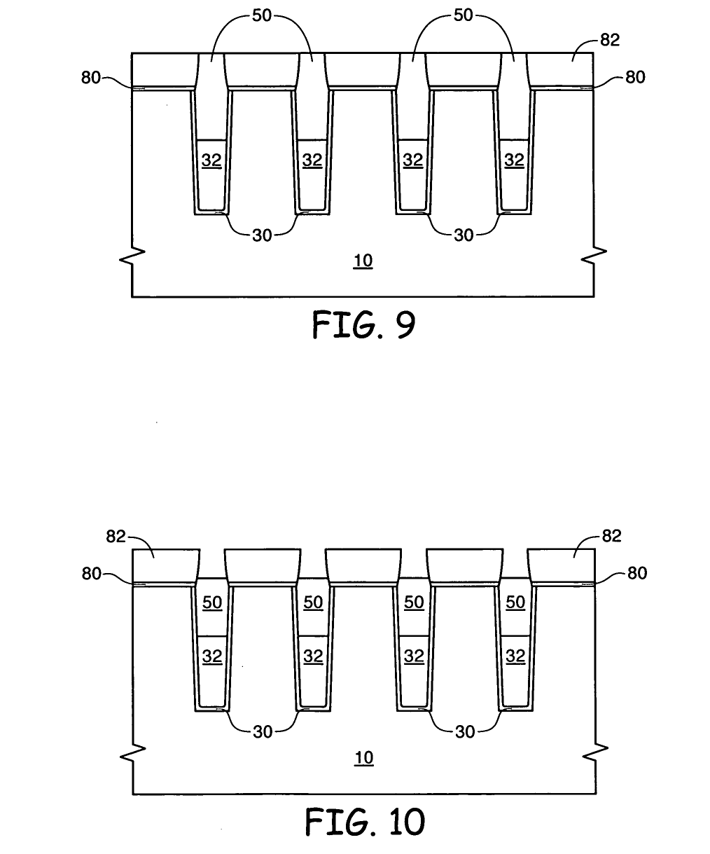

Next, the FIG. 8 structure, specifically polysilicon 82 is planarized, for example using CMP to result in the structure of FIG. 9. The planarization will be typically targeted to terminate just as the second fill layer 50 is completely exposed to maximize the thickness of the completed floating gate. The second fill layer 50 is partially etched so that it is recessed within the polysilicon features 82 as depicted in FIG. 10. The etch of the second fill layer is targeted so that the tunnel oxide 80 is not exposed, as damage to the tunnel oxide may result if it is exposed to the etch.

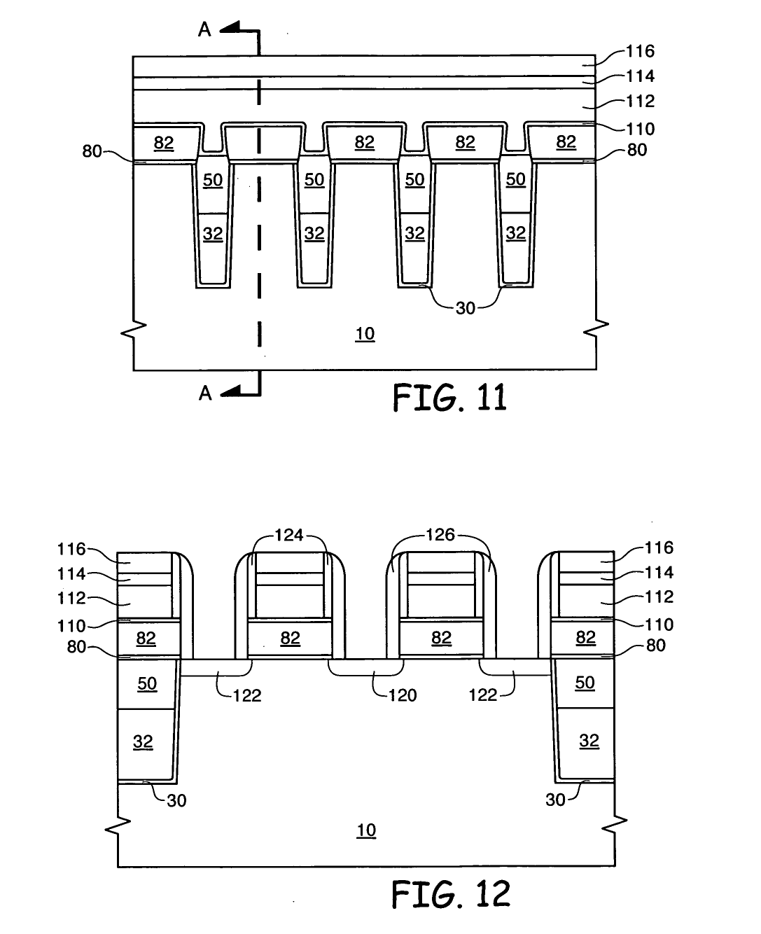

Next, an intergate dielectric layer 110 such as a capacitor cell dielectric formed from a silicon nitride layer interposed between two silicon dioxide layers (i.e. an “ONO” layer, depicted for simplicity as a single layer in FIG. 11) is formed. Subsequently, a conductive layer such as another polysilicon layer is formed, along with other layers such as a silicide layer 114 and a dielectric capping layer 116 according to techniques known in the art. These structures provide a plurality of control gates one of which is depicted in FIG. 11. As is known in the art, the control gate and a bit line (not depicted) used together to access the individual floating gates 82 for read and program operations. Subsequent wafer processing acts may then be performed according to techniques known in the art to form a completed semiconductor device, such as a flash memory device.

FIG. 12 depicts the FIG. 11 device along A-A and may include structures formed during additional processing acts. In addition to like-numbered structures of FIG. 11, FIG. 12 depicts a source region 120 and drain regions 122 implanted into the semiconductor wafer 10, first spacers 124 and second spacers 126 formed around the floating gate 82 and the control gate 112, 114. Variations to the structure of FIG. 12 and the other FIGS. are possible without departing from the scope of the invention.

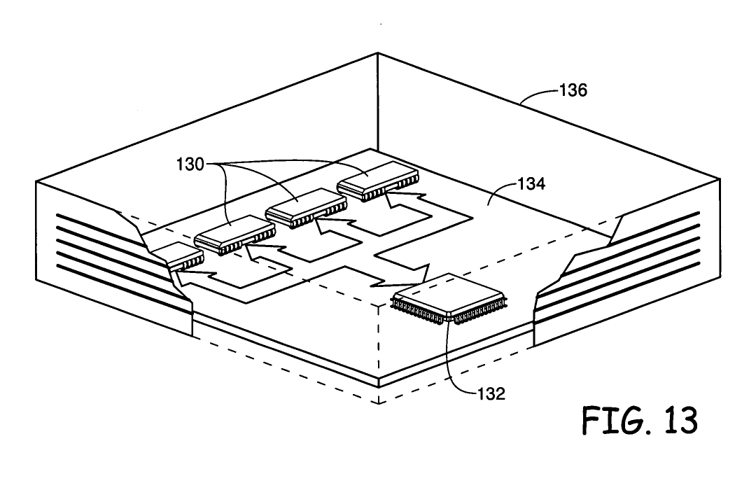

As depicted in FIG. 13, a semiconductor memory device 130 may be attached along with other devices such as a microprocessor 132 to a printed circuit board 134, for example to a computer motherboard or as a part of a memory module used in a personal computer, a minicomputer, or a mainframe 136. The microprocessor and/or memory devices may comprise an embodiment of the present invention. FIG. 13 may also represent use of device 130 in other electronic systems comprising a housing 136, for example systems comprising a microprocessor 132, related to telecommunications, the automobile industry, semiconductor test and manufacturing equipment, consumer electronics, or virtually any piece of consumer or industrial electronic equipment.

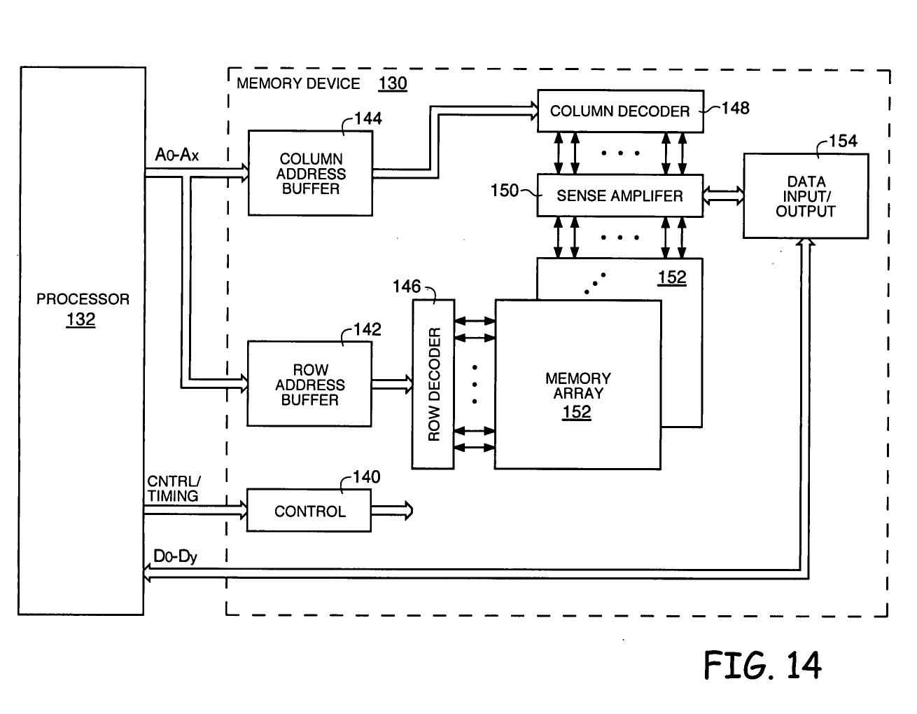

The process and structure described herein can be used to manufacture a number of different structures comprising shallow trench isolation formed according to the inventive process. FIG. 14, for example, is a simplified block diagram of a memory device such as a dynamic random access memory having STI which may be formed using an embodiment of the present invention. The general operation of such a device is known to one skilled in the art. FIG. 14 depicts a processor 132 coupled to a memory device 130, and further depicts the following basic sections of a memory integrated circuit: control circuitry 140; row address buffer 142; column address buffer 144; row decoder 146; column decoder 148; sense amplifier 150; memory array 152; and data input/output 154.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. For example, an embodiment of the invention may be used to form isolation within openings or recesses other than the trench described herein. It is therefore contemplated that the appended claims will cover any such modifications or embodiments as fall within the true scope of the invention.

1. A method used in fabrication of a semiconductor device, comprising:
providing a semiconductor wafer having at least one opening therein, wherein the at least one opening has a depth;
forming a first fill layer within the at least one opening such that the first fill layer only partially fills the at least one opening, wherein a remainder of the at least one opening remains unfilled by the first fill layer and the first fill layer has a first flowability and a first electrical isolation value; and
forming a second fill layer within the remainder of the at least one opening on the first fill layer, wherein the second fill layer has a second flowability which is less than the first flowability and a second electrical isolation value which is greater than the first electrical isolation value, and the first fill layer and the second fill layer together provide an electrical isolation layer.

2. The method of claim 1 further comprising:
forming a dielectric liner on the semiconductor wafer and within the trench prior to forming the first fill layer; and
forming the first fill layer on the dielectric liner.

3. The method of claim 2 further comprising:
forming a silicon nitride layer over the semiconductor wafer;
etching the silicon nitride layer and the semiconductor wafer to form the at least one opening in the semiconductor wafer; and
forming the dielectric liner on the silicon nitride layer.

4. The method of claim 1 further comprising:
forming the first fill layer to completely fill the at least one opening; and
etching the first fill layer such that the first fill layer only partially fills the at least one opening, wherein a remainder of the at least opening remains unfilled by the first fill layer.

5. The method of claim 1 further comprising forming the first fill layer from a material selected from the group consisting of silicon nitride, polysilicon, and amorphous carbon.

6. The method of claim 5 further comprising forming the second fill layer from silicon dioxide.

7. The method of claim 1 wherein the first fill layer and the second fill layer together provide shallow trench isolation.

8. A method used in fabrication of a semiconductor device, comprising:
forming a pad oxide layer over a semiconductor wafer;
forming a blanket sacrificial silicon nitride layer on the pad oxide layer;
patterning the blanket sacrificial silicon nitride layer, the pad oxide layer, and the semiconductor wafer to form at least one trench defined by an opening in the sacrificial silicon nitride layer, the pad oxide, and the semiconductor wafer;
forming a blanket liner on the semiconductor wafer within the at least one trench;
forming a first fill layer within the at least one trench such that the first fill layer only partially fills the at least one trench, wherein the first fill layer has a first flowability and a first electrical isolation value;
forming a second fill layer within the at least one trench such that an upper surface of the second fill layer is about level with an upper surface of the sacrificial silicon nitride layer, and the second fill layer has a second flowability which is less than the first flowability and a second electrical isolation value which is greater than the first electrical isolation value;
subsequent to forming the second fill layer, removing the sacrificial silicon nitride layer such that the second fill layer protrudes from the semiconductor wafer;
forming a conductive floating gate layer over the semiconductor wafer and over the second fill layer;
planarizing the conductive floating gate layer such that an upper surface of the conductive floating gate layer is about even with an upper surface of the second fill layer;
subsequent to planarizing the conductive floating gate layer, etching the second fill layer such that the upper surface of the second fill layer is below the upper surface of the sacrificial silicon nitride layer;
forming a capacitor cell dielectric layer on the conductive floating gate layer and on the second fill layer; and
forming a control gate layer on the capacitor cell dielectric layer.

9. The method of claim 8 further comprising:
forming the second fill layer over sacrificial silicon nitride layer; and
planarizing the upper surface of the second fill layer such that the upper surface of the second fill layer is about level with the upper surface of the sacrificial silicon nitride layer.

10. The method of claim 8 further comprising:
forming the first fill layer from a material selected from the group consisting of silicon nitride, polysilicon, and amorphous carbon; and
forming the second fill layer from silicon dioxide.

11. The method of claim 8 further comprising:
forming the first fill layer on the liner; and
forming the second fill layer on the first fill layer and on the liner.

12. A semiconductor device, comprising:
a portion of a semiconductor wafer having at least one trench therein;
a shallow trench isolation layer within the at least one trench, comprising:
a first fill layer partially filling the trench; and
a second fill layer formed on the first fill layer;
a tunnel oxide layer formed on the portion of the semiconductor wafer;
a transistor floating gate formed on the tunnel oxide layer;
a capacitor cell dielectric layer formed on the second fill layer and on the transistor floating gate; and
a transistor control gate on the capacitor cell dielectric layer and overlying the transistor floating gate, the first fill layer, and the second fill layer.

13. The semiconductor device of claim 12 wherein:
the first fill layer comprises a material selected from the group consisting of silicon nitride, polysilicon, and amorphous silicon; and
the second fill layer comprises silicon dioxide.

14. The semiconductor device of claim 12 wherein the floating gate comprises a damascene polysilicon layer.

15. The semiconductor device of claim 12, wherein:
the first fill layer is first material having a first flowability and a first isolation value; and
the second fill layer is a second material having a second flowability which is less than the first flowability and a second isolation value which is greater than the first isolation value.

16. The semiconductor device of claim 12 wherein the at least one trench comprises a tapered profile, and the at least one trench is wider at an upper portion of the at least one trench than at a lower portion of the at least one trench.

17. An electronic system comprising a semiconductor device, wherein the semiconductor device comprises:
a portion of a semiconductor wafer having at least one trench therein;
a shallow trench isolation layer within the at least one trench, comprising:
a first fill layer partially filling the trench; and
a second fill layer formed on the first fill layer;
a tunnel oxide layer formed on the portion of the semiconductor wafer;
a transistor floating gate formed on the tunnel oxide layer;
a capacitor cell dielectric layer formed on the second fill layer and on the transistor floating gate; and
a transistor control gate on the capacitor cell dielectric layer and overlying the transistor floating gate, the first fill layer, and the second fill layer.

18. The electronic system of claim 17 wherein the semiconductor device is one of a memory device and a microprocessor.

19. The electronic system of claim 17 wherein the semiconductor device further comprises:
the first fill layer comprises a material selected from the group consisting of silicon nitride, polysilicon, and amorphous silicon; and
the second fill layer comprises silicon dioxide.

20. The electronic system of claim 17, wherein the semiconductor device further comprises:
the first fill layer is first material having a first flowability and a first isolation value; and
the second fill layer is a second material having a second flowability which is less than the first flowability and a second isolation value which is greater than the first isolation value.
